(19) United States
(12) Patent Application Publication
(10) Pub. No.: US 2024/0418795 A1
(43) Pub. Date: Dec. 19, 2024

(54) METHOD FOR DETECTING INTERNAL SHORT CIRCUIT OF POWER BATTERY

(71) Applicant: BEIJING NATIONAL NEW ENERGY VEHICLE TECHNOLOGY INNOVATION CENTER CO., LTD., Beijing (CN)

(72) Inventors: Feng ZHU, Beijing (CN); Lei ZONG, Beijing (CN); Feng DU, Beijing (CN); Chengyin YUAN, Beijing (CN); Guangcai ZOU, Beijing (CN)

(21) Appl. No.: 18/702,415

(22) PCT Filed: Aug. 11, 2022
(86) PCT No.: PCT/CN2022/111847

§ 371 Date: Apr. 18, 2024

(30) Foreign Application Priority Data
Dec. 22, 2021 (CN) 202111578594.0

(51) Int. Cl. G01R 31/52; G01R 31/367

(52) U.S. Cl. CPC G01R 31/52; G01R 31/367

(57) ABSTRACT

A method for detecting internal short circuit of a power battery, comprising: simulating a triggered internal short circuit fault during operation process of the battery, sorting the parameters according to the order of the abnormal value occurrence time, calculating a weight coefficient of each characteristic parameter through the abnormal value occurrence time and analytical hierarchy process to ensure calculation consistency ratio is less than 0.1; collecting data of battery parameters during operation; if a certain judgement characteristic parameter exceeds the set threshold, a risk coefficient of the characteristic parameter is calculated; a risk value of the internal short circuit of the battery is calculated according to the weight coefficient and the risk coefficient; if the risk value continues to rise, it is determined that the battery has internal short circuit. By means of the method, weight coefficients in an analytic hierarchy process are calculated on the basis of the occurrence time of characteristic parameter, and the aim of early judgement is achieved by means of decreasing a characteristic parameter judgement threshold value. In conjunction with online monitored states of various parameters, a change feature of a risk value of a battery in a specific working condition is calculated, and the risk of internal short circuit is finally determined.

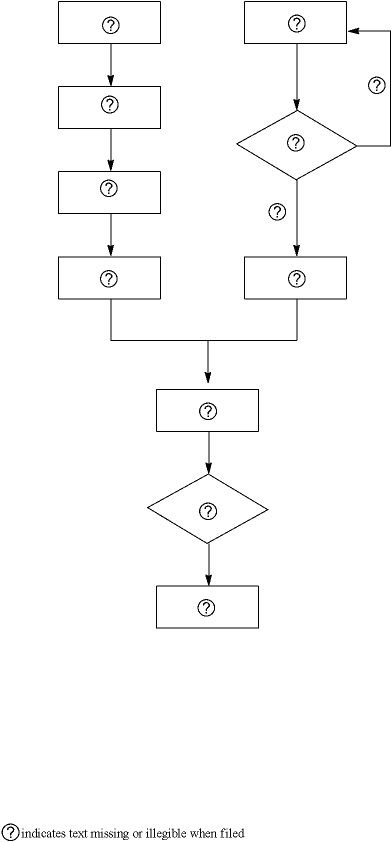

### FIELD OF TECHNOLOGY

The present invention relates to the field of new energy technology, and specifically relates to a short-circuit detection method within a power battery.

### BACKGROUND

At present, the most concerning safety issue for power battery is battery fire. This kind of accident is easy to trigger, has multiple causes, and burns violently. According to statistics, 38% of new energy vehicle fire accidents from 2014 to 2019 were caused by battery spontaneous combustion, ranking first among various causes. The main reason for the spontaneous combustion of power batteries is that the battery has an internal short-circuit fault. The fault is not easy to detect at the beginning. After the short-circuit resistance drops to a certain level, a momentary “surge” phenomenon will occur inside the battery, causing the temperature at the short-circuit position to rise rapidly, leading to thermal runaway of the battery. There are many reasons for the internal short circuit in the battery, such as overcharge and over-discharge during use, battery deformation caused by car collisions, and the introduction of impurities during the preparation process. Therefore, strictly monitoring changes in key parameters of power batteries to achieve early warning of the internal short circuit is an important direction to ensure the safety of power batteries.

In existed research, many battery operating parameters can be used as characteristic values to judge internal short circuit. In GB/T 38661-2020, it is stipulated that parameters such as voltage, current, voltage difference, temperature, temperature difference, and SOC can be used as parameters to determine battery system faults. In addition, there are also high-order characteristic parameters calculated based on basic measurement parameters that can be used as characteristic values to determine the internal short circuit of the battery, such as the relaxation voltage characteristics in patent CN202010456801.4, the peak height of the incremental capacity curve in patent CN202110125389.2, the peak area of the incremental capacity curve in patent CN202110125387.3, and the initial capacity difference in patent CN202010988403.7.

Existed detection methods mostly use a single parameter to make fault determinations, or use several characteristic parameters to determine whether they reach a threshold, which may lead to risks of misjudgment or delayed diagnosis. In fact, after the internal short circuit occurs, the abnormal values of many characteristic parameters appear in a certain sequence. However, no one in the prior art has detected the internal short circuit fault in the battery through the time sequence that the abnormal values of several characteristic parameters occur.

### SUMMARY

The present disclosure provides a method for detecting internal short circuit of a power battery. The method identifies the time sequence of abnormal values of multiple characteristic parameters occur, and combines the analytic hierarchy process and characteristic parameter deviation degree to calculate the change of the risk value of the battery, thereby more quickly and accurately detect whether internal short circuit fault has occurred in the battery.

The technical solution adopted by the present disclosure is:

A method for detecting internal short circuit of a power battery, comprising:
simulating a triggered internal short circuit fault during operation process of the battery, recording changes of various parameters before and after the internal short circuit is triggered; setting a range of threshold for each parameter, recording time when each parameter reaches the threshold after the internal short circuit is triggered as abnormal value occurrence time, sorting the parameters according to the order of the abnormal value occurrence time, and selecting several parameters as characteristic parameters;
calculating a weight coefficient of each characteristic parameter through the abnormal value occurrence time and analytical hierarchy process to ensure calculation consistency ratio CR is less than 0.1;
collecting data of parameters of the battery during operation;
if a certain judgement characteristic parameter exceeds the set threshold, a risk coefficient of the characteristic parameter is calculated;
a risk value of the internal short circuit of the battery is calculated according to the weight coefficient and the risk coefficient;
if the risk value continues to rise or rises stepwise, it is determined that the battery has internal short circuit.

Preferably, a method of simulating the operation process of the battery is one or more of designing a replacement experiment of the internal short circuit of the battery and establishing a simulation model for the internal short circuit of the battery.

Preferably, the parameters include voltage, current, pressure difference, temperature, temperature difference, temperature rise rate, SOC, SOH, and internal resistance.

Preferably, the selecting process of selecting partial parameters as characteristic parameters further comprising:
taking several parameters with earliest occurrence of anomalies as judgement characteristic parameters for triggering judgement of internal short circuit process.

Preferably, calculating a weight coefficient of each characteristic parameter through the abnormal value occurrence time and analytical hierarchy process to ensure calculation consistency ratio CR is less than 0.1 further comprising:
sorting the characteristic parameters based on the order of the abnormal value occurrence time, and the sorted characteristic parameters are C1, C2, C3 . . . Ci, the abnormal value occurrence times are t1, t2, t3 . . . ti;
dividing a time period from the occurrence time ti of last abnormal value to time t0 of the triggered internal short circuit into N segments on average, and marking them as N numbers of N to 1;
assigning a number to each characteristic parameter based on a period the abnormal value occurrence time t of belonging to, that is, characteristic numbers of the characteristic parameters C1, C2, C3. . . . Ci are M1, M2, M3. . . . Mi;
constructing a judgment matrix for the analytic hierarchy process, wherein aij represents a relative importance of characteristic parameter i to characteristic parameter j, aij=Mi−Mj+1, while also ensuring that aij×aji=1 and aii=1;
according to the above steps, calculating the weight coefficient of each characteristic parameter P1, P2, P3. . . . Pi using the analytic hierarchy process to ensure the calculation consistency ratio CR is less than 0.1.

Preferably, N is 9.

Preferably, collecting data of parameters of the battery during operation further comprising:
collecting data of each parameter of the battery during operation, monitoring a corresponding characteristic parameter under this operating condition, and calculating an average value Lₐᵥₑ of the characteristic parameters; the average value is an arithmetic average value after a maximum value Lₘₐₓ and a minimum value Lₘᵢₙ are removed,

$${L}_{ave} = \frac{1}{n - 2} {\sum }_{i = 1}^{n - 2} {L}_{i} .$$

Preferably, the average value Lₐᵥₑ serves as a standard value for the characteristic parameter involving difference.

Preferably, if a certain judgement characteristic parameter exceeds the set threshold, a risk coefficient of the characteristic parameter is calculated further comprising:
if a certain characteristic parameter C1 of the battery exceeds the set threshold L_{threhold}, starting calculation of the risk value, and calculating a deviation of the characteristic parameter from the threshold D=(Lᵢ−L_{threhold})/L_{threhold}, or determining a fault value as 1.

Preferably, a risk value of the internal short circuit of the battery is calculated according to the weight coefficient and the risk coefficient further comprising:
calculating the risk value of the internal short circuit of the battery according to the weight coefficient P and the risk coefficient Q,

$$R = {\sum }_{i = 1}^{i} {P}_{i} {Q}_{i} ;$$

wherein the risk coefficient Q is the deviation or the fault value.

Preferably, simulate and calculate the characteristic parameters and their weight coefficients under different internal short circuit conditions, obtain the distribution range of the weight coefficient of each characteristic parameter with the change of internal short circuit resistance value, and calculate the value from this range during actual judgment, thereby improving the adaptability of the algorithm.

The beneficial effect of the present disclosure lies in the combination of previous research (simulating the characteristic changes after triggering internal short circuit of the battery during operation) and online monitoring (collecting battery parameter data during operation). Firstly, through previous research, the weight coefficients in the analytic hierarchy process are calculated based on the occurrence time of multiple characteristic parameters, and the judgment threshold for characteristic parameter can be appropriately reduced to achieve the purpose of early judgment; afterwards, by monitoring the status of various parameters online, the variation characteristics of battery risk values under specific working conditions are calculated, and the risk of internal short circuit is ultimately determined. The present disclosure has a high accuracy in determining internal short circuit faults in batteries, and can also advance the determination time of internal short circuits.

### BRIEF DESCRIPTION OF THE DRAWINGS

FIG. 1 is a flowchart of the method for detecting internal short circuit of a power battery according to an embodiment of the present disclosure;

FIG. 2 is a variation curve of the battery risk value over time according to the method for detecting internal short circuit of a power battery in the specific embodiment 1 of the present disclosure;

FIG. 3 is a variation curve of the battery risk value over time according to the method for detecting internal short circuit of a power battery in the specific embodiment 2 of the present disclosure.

### DESCRIPTION OF THE EMBODIMENTS

In order to describe the technical content, achieved goals and effects of the present invention in detail, the following descriptions will be made in conjunction with the embodiments and accompanying drawings.

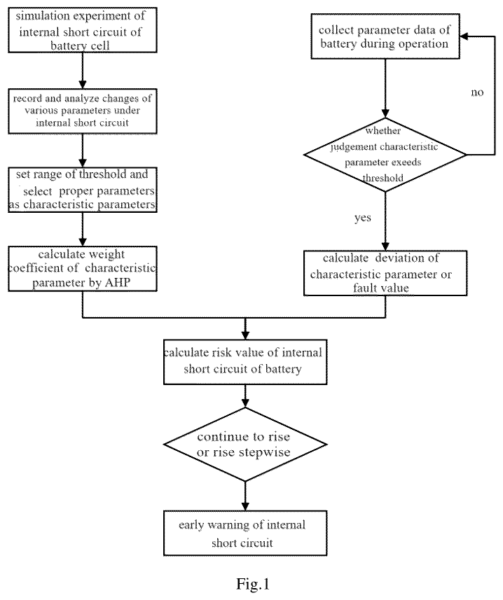

Please refer to FIG. 1, a method for detecting internal short circuit of a power battery, comprising:
Step 11: designing a replacement experiment for internal short circuit of a battery or establishing a simulation model for internal short circuit of a battery, so as to simulate changes of characteristic parameter after internal short circuit is trigged during operation of the battery.
Step 12: recording changes of various parameters before and after the internal short circuit is triggered, including measured parameters such as voltage, current, pressure difference, temperature, temperature difference, temperature rise rate, etc., or parameters calculated by the model such as SOC, SOH, internal resistance, etc.
Step 13: setting a range of threshold for each parameter, recording time when each parameter reaches the threshold after the internal short circuit is triggered as abnormal value occurrence time, sorting the parameters according to the order of the abnormal value occurrence time, and selecting proper parameters as characteristic parameters. One or several parameters with the earliest anomalies can be used as the judgement characteristic parameters that trigger the judgment process. In addition, the threshold range of parameters can refer to relevant regulations in national standards and battery management systems. In order to improve judgment sensitivity, the threshold range of each parameter can also be appropriately reduced.
Step 14: calculating a weight coefficient of each characteristic parameter through the abnormal value occurrence time and analytical hierarchy process, the details are as follows. Sorting the characteristic parameters based on the order of the abnormal value occurrence time, and the sorted characteristic parameters are C1, C2, C3. . . . Ci, the abnormal value occurrence time is t1, t2, t3 . . . ti; dividing a time period from the occurrence time ti of last abnormal value to time to of the triggered internal short circuit into 9 segments on average, and marking them as numbers 9-1; assigning a number to each characteristic parameter based on the period the abnormal value occurrence time t belonging to, that is, characteristic numbers of the characteristic parameters C1, C2, C3. . . . Ci are M1, M2, M3. . . . Mi; constructing a judgment matrix for the analytic hierarchy process, wherein aij represents a relative importance of characteristic parameter i to characteristic parameter j, aij=Mi−Mj+1, while also ensuring that aij×aji=1 and aii=1.

According to the above steps, calculating the weight coefficient of each characteristic parameter P1, P2, P3. . . . Pi using the analytic hierarchy process to ensure the calculation consistency ratio CR is less than 0.1.
Step 15: it is possible to calculate the characteristic parameters and their weight coefficients under various working conditions, thereby expanding the judgment range of the algorithm.

The steps for online monitoring are as follows:
Step 21: collecting data of each parameter of the battery during operation, monitoring a corresponding characteristic parameter under this operating condition, and calculating an average value Lₐᵥₑ of the characteristic parameters; the average value is an arithmetic average value after a maximum value Lₘₐₓ and a minimum value Lₘᵢₙ are removed,

$${L}_{ave} = \frac{1}{n - 2} {\sum }_{i = 1}^{n - 2} {L}_{i} ,$$

the average value Lₐᵥₑ serves as a standard value for the characteristic parameter involving difference.
Step 22: if a certain judgement characteristic parameter C1 of the battery exceeds the set threshold L_{threhold}, starting calculation of the risk value, and calculating a deviation of the characteristic parameter from the threshold D=(Lᵢ−L_{threhold})/L_{threhold}, or determining a fault value as 1.
Step 23: calculating the risk value of the internal short circuit of the battery according to the weight coefficient P and the risk coefficient Q,

$$R = {\sum }_{i = 1}^{i} {P}_{i} {Q}_{i} ;$$

wherein the risk coefficient Q is the deviation or the fault value.
Step 24: if the risk value continues to rise or steps up, it can be determined that the battery has internal short circuit.

### Embodiment 1

For a 2770180 type lithium iron phosphate battery with a capacity of 20 Ah, use the method for detecting internal short circuit of a power battery in this disclosure. Firstly, establish an electric thermal internal short circuit coupling model, set the internal short circuit resistance to 1Ω, and trigger it when discharging for 1000s with a discharge current of 1C. The selected characteristic parameters are pressure difference ΔV, surface temperature T, surface temperature difference ΔT, and surface temperature rise rate dT/dt, wherein the pressure difference and temperature difference are the differences between the short-circuit battery and the normal battery. Considering the alarming threshold of the battery management system, the thresholds for the above four parameters are set to 0.1 V, 60° C., 7° C., and exceeding twice of the normal surface temperature rise rate, respectively. By analyzing the characteristic parameters of the battery, the time when each characteristic parameter reaches the above threshold is obtained, and the characteristic numbers are calculated based on the order of occurrence. The results are shown in the table below:

| parameter | dT/dt | ΔT | T | ΔV |
|---|---|---|---|---|
| time (s) | 1050 | 1218 | 2572 | 2887 |
| characteristic | 9 | 8 | 2 | 1 |
| number M | | | | |

Based on the characteristic numbers of the four characteristic parameters, the judgment matrix of the AHP is established, and the results are as follows:

| | dT/dt | ΔT | T | ΔV |
|---|---|---|---|---|
| dT/dt | 1 | 2 | 8 | 9 |
| ΔT | ½ | 1 | 7 | 8 |
| T | ⅛ | 1/7 | 1 | 2 |
| ΔV | 1/9 | ⅛ | ½ | 1 |

Calculate the weight coefficients and consistency coefficient of the four parameters through the analytic hierarchy process, and the results are as follows. The consistency coefficient CR<0.1 shows that the result is valid.

| | | | | | consistency |
|---|---|---|---|---|---|
| parameter | dT/dt | ΔT | T | ΔV | coefficient CR |
| weight | 0.534 | 0.354 | 0.067 | 0.0445 | 0.0281 |
| coefficient P | | | | | |

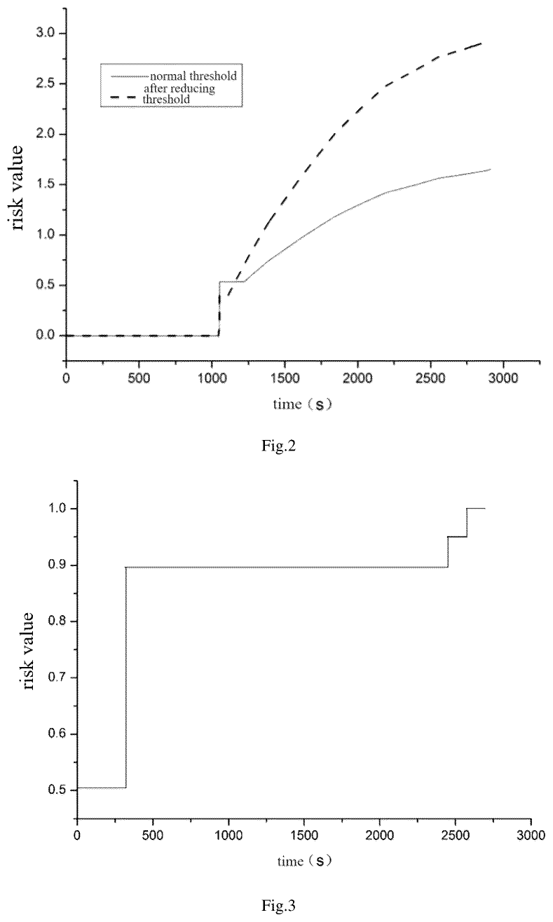

The characteristic parameter dT/dt with the earliest occurrence of an abnormal value is used as the judgment characteristic parameter. When calculating the risk coefficient corresponding to each parameter, it is processed according to the logical relationship, that is, as long as it exceeds the threshold, the risk coefficient is set to 1, and the deviation is calculated for other parameters. After that, the weight coefficient of each characteristic parameter is multiplied by the risk coefficient and then summed. The change curve of the battery risk value over time can be obtained, as shown in FIG. 2. Under actual operating conditions, if the risk value of the judgment characteristic parameter is non-zero, firstly there is a 53.4% risk of internal short circuit, and then if the risk value continues to rise with discharge, it can be further determined to be internal short circuit.

In addition, the range of some parameters can also be appropriately reduced, such as reducing the values of the above temperature T and surface temperature difference ΔT from the industry-accepted 60° C. and 7° C. to 40° C. and 4° C. Then, calculate the battery risk value according to the above steps, which can not only bring forward the identification time of internal short circuit appropriately, but also reduce the probability of misjudgment.

### Embodiment 2

For a 2770180 type lithium iron phosphate battery with a capacity of 20 Ah, use the method for detecting internal short circuit of a power battery in this disclosure. Firstly, establish an electric thermal internal short circuit coupling model, set the internal short circuit resistance to 1Ω, assume that an internal short-circuit occurs during the resting process, and the initial SOC is 0.7 due to self-discharge, while other normal series-connected batteries have an SOC of 0.95. The discharge current of 1C. The selected characteristic parameters are pressure difference AΔ, temperature T, surface temperature difference AΔ, and surface temperature rise rate dT/dt, wherein the pressure difference and temperature difference are the differences between the short-circuit battery and the normal battery. Considering the alarming threshold of the battery management system, the thresholds for the above four parameters are set to 0.1 V, 60° C., 7° C., and exceeding twice of the normal surface temperature rise rate, respectively. By analyzing the characteristic parameters of the battery, the time when each characteristic parameter reaches the above threshold is obtained, and the characteristic numbers are calculated based on the order of occurrence. The results are shown in the table below:

| parameter | dT/dt | ΔT | ΔV | T |
|---|---|---|---|---|
| time (s) | 50 | 333 | 2446 | 2555 |
| characteristic | 9 | 8 | 1 | 1 |
| number M | | | | |

Based on the characteristic numbers of the four characteristic parameters, the judgment matrix of the AHP is established, and the results are as follows:

| | dT/dt | ΔT | ΔV | T |
|---|---|---|---|---|
| dT/dt | 1 | 1 | 8 | 9 |
| ΔT | 1 | 1 | 7 | 8 |
| ΔV | ⅛ | 1/7 | 1 | 1 |
| T | 1/9 | ⅛ | 1 | 1 |

Calculate the weight coefficients and consistency coefficient of the four parameters through the analytic hierarchy process, and the results are as follows. The consistency coefficient CR<0.1 shows that the result is valid.

| | | | | | consistency |
|---|---|---|---|---|---|
| parameter | dT/dt | ΔT | ΔV | T | coefficient CR |
| weight | 0.507 | 0.391 | 0.0521 | 0.0488 | 0.0789 |
| coefficient P | | | | | |

Use the characteristic parameter dT/dt with the earliest occurrence of an abnormal value as the judgment characteristic parameter. When calculating the risk coefficient corresponding to each parameter coefficient, all characteristic parameters are processed according to logical relationships, that is, as long as the characteristic parameter exceeds the threshold, its risk coefficient is set to 1. After that, the weight coefficient of each characteristic parameter is multiplied by the risk coefficient and then summed. The change curve of the battery risk value over time can be obtained, as shown in FIG. 3. Under actual operating conditions, if the temperature rise coefficient is first found to exceed the threshold, then there is a 50.7% risk of internal short circuit, and then if the temperature difference coefficient also exceeds the threshold, there is an 89.8% risk of internal short circuit.

In summary, the present invention determines the possibility of internal short circuit through changes in risk values; in the analytic hierarchy process, a judgment matrix is established based on the occurrence time of abnormal values under specific working conditions, which can be more objective to evaluate the weight coefficient of each characteristic parameter in the internal short circuit determination process.

The above description is only an embodiment of the present invention, and does not limit the patent scope of the present invention. All equivalent transformations made by using the description of the present invention and the contents of the accompanying drawings, or directly or indirectly used in related technical fields, are all included in the same principle. Within the scope of patent protection of the present invention.

What is claimed is:

1. A method for detecting internal short circuit of a power battery, comprising:
simulating a triggered internal short circuit fault during operation process of the battery, recording changes of various parameters before and after the internal short circuit is triggered; setting range of threshold for each parameter, recording time when each parameter reaches the threshold after the internal short circuit is triggered as abnormal value occurrence time, sorting the parameters according to an order of the abnormal value occurrence time, and selecting partial parameters as characteristic parameters;
calculating a weight coefficient of each characteristic parameter through the abnormal value occurrence time and analytical hierarchy process to ensure calculation consistency ratio CR is less than 0.1;
collecting data of parameters of the battery during operation;
if a certain judgement characteristic parameter exceeds the set threshold, a risk coefficient of the characteristic parameter is calculated;
a risk value of the internal short circuit of the battery is calculated according to the weight coefficient and the risk coefficient;
if the risk value continues to rise or rises stepwise, it is determined that the battery has internal short circuit.

2. The method for detecting internal short circuit of a power battery according to claim 1, wherein a method of simulating the operation process of the battery is one or more of designing a replacement experiment of the internal short circuit of the battery and establishing a simulation model for the internal short circuit of the battery.

3. The method for detecting internal short circuit of a power battery according to claim 1, wherein the parameters include voltage, current, pressure difference, temperature, temperature difference, temperature rise rate, SOC, SOH, and internal resistance.

4. The method for detecting internal short circuit of a power battery according to claim 1, wherein partial parameters are selected as characteristic parameters, the number of characteristic parameters is equal to or greater than 3, and selecting partial parameters as characteristic parameters further comprising:
taking several parameters with earliest occurrence of anomalies as judgement characteristic parameters for triggering process of judging internal short circuit.

5. The method for detecting internal short circuit of a power battery according to claim 1, wherein calculating a weight coefficient of each characteristic parameter through the abnormal value occurrence time and analytical hierarchy process to ensure calculation consistency ratio CR is less than 0.1 further comprising:
sorting the characteristic parameters based on the order of the abnormal value occurrence time, and the sorted characteristic parameters are C1, C2, C3. . . . Ci, the abnormal value occurrence times are t1, t2, t3 . . . ti;
dividing a time period from occurrence time ti of last abnormal value to time t0 of the triggered internal short circuit into N segments on average, and marking them as N numbers;
assigning a number to each characteristic parameter based on a period the abnormal value occurrence time t belonging to, that is, characteristic numbers of the characteristic parameters C1, C2, C3. . . . Ci are M1, M2, M3. . . . Mi;
constructing a judgment matrix for the analytic hierarchy process, wherein aij represents importance of characteristic parameter i relative to characteristic parameter j, aij=Mi−Mj+1, while also ensuring that aij×aji=1 and aii=1;
according to the above steps, calculating the weight coefficient of each characteristic parameter P1, P2, P3. . . . Pi using the analytic hierarchy process to ensure the calculation consistency ratio CR is less than 0.1.

6. The method for detecting internal short circuit of a power battery according to claim 5, wherein N is 9.

7. The method for detecting internal short circuit of a power battery according to claim 5, wherein collecting data of parameters of the battery during operation further comprising:
collecting data of each parameter of the battery during operation, monitoring a corresponding characteristic parameter under this operating condition, and calculating an average value Lₐᵥₑ of the characteristic parameter, the average value is an arithmetic average value after a maximum value Lₘₐₓ and a minimum value Lₘᵢₙ are removed,
$${L}_{ave} = \frac{1}{n - 2} {\sum }_{i = 1}^{n - 2} {L}_{i} .$$

8. The method for detecting internal short circuit of a power battery according to claim 7, wherein the average value Lₐᵥₑ serves as a standard value for the characteristic parameter involving difference.

9. The method for detecting internal short circuit of a power battery according to claim 7, wherein if a certain judgement characteristic parameter exceeds the set threshold, a risk coefficient of the characteristic parameter is calculated, further comprising:
if a certain characteristic parameter C1 of the battery exceeds the set threshold L_{threhold}, starting calculation of the risk value, and calculating a deviation of the characteristic parameter from the threshold D=(Lᵢ−L_{threhold})/L_{threhold}, or determining a fault value as 1.

10. The method for detecting internal short circuit of a power battery according to claim 9, wherein a risk value of the internal short circuit of the battery is calculated according to the weight coefficient and the risk coefficient further comprising:
calculating the risk value of the internal short circuit of the battery according to the weight coefficient P and the risk coefficient Q, R=Σᵢ₌₁ⁱPᵢQᵢ;
wherein the risk coefficient Q is the deviation or the fault value.
